(19) United States
(12) Patent Application Publication
(10) Pub. No.: US 2025/0280518 A1
(43) Pub. Date: Sep. 4, 2025

(54) TIME-DEPENDEND OVERTEMPERATURE PROTECTION

(71) Applicant: Infineon Technologies AG, Neubiberg (DE)

(72) Inventor: Stephan Donath, Neubiberg (DE)

(21) Appl. No.: 19/012,685

(22) Filed: Jan. 7, 2025

(30) Foreign Application Priority Data
Mar. 1, 2024 (DE) 102024201944.5

(51) Int. Cl. H05K 7/20; G01K 3/04; G08B 21/18

(52) U.S. Cl. CPC H05K 7/20845; G01K 3/04; G08B 21/182; G01K 2219/00

(57) ABSTRACT

A method for overtemperature protection of an electronic device (112) is presented. The method comprises:
a) monitoring a temperature of at least a part of the electronic device (112);
b) if the temperature exceeds a temperature threshold, starting to monitor a time of temperature exceedance; and
c) if the time of temperature exceedance exceeds a time threshold, declaring an overtemperature condition of the electronic device (112).

Further, an overtemperature detection circuit (110) and a use of the overtemperature detection circuit (110) and the method for overtemperature protection are presented.

### TECHNICAL FIELD

The present disclosure relates to a method for overtemperature protection, an overtemperature detection circuit and a use thereof.

### BACKGROUND

Overtemperature operation may generally destroy or at least damage electronic devices and specifically semiconductor devices. At least, overtemperature operation may reduce lifetime of such devices or may lead to operation failures of them. Additionally or alternatively, the overtemperature may cause a failure or a malfunctioning of such devices. Thus, overtemperature detection and protection is typically required. However, such devices typically comprise a plurality of different materials and each material may have different properties, specifically with respect to temperature behavior. As an example, a printed circuit board material may show a different temperature behavior compared to a semiconductor material. Thus, the different materials may have different operation temperature ranges. In other words, temperature thresholds for overtemperature operation may be different for them. As an example, the before mentioned printed circuit board material may have a lower temperature threshold for overtemperature operation than the semiconductor material. However, the printed circuit board material may be capable of withstanding its respective lower temperature threshold for overtemperature operation at least over a limited amount of time. Generally, materials may be rugged with respect to high operation temperatures for at least short time periods. Thus, there is a need for improving overtemperature protection and specifically for making use of said ruggedness against high operation temperatures over limited time periods.

### SUMMARY

In a first aspect, a method for overtemperature protection of an electronic device is presented. The method comprises:
a) monitoring a temperature of at least a part of the electronic device;
b) if the temperature exceeds a temperature threshold, starting to monitor a time of temperature exceedance;
c) if the time of temperature exceedance exceeds a time threshold, declaring an overtemperature condition of the electronic device.

In a further aspect, an overtemperature detection circuit is presented. The overtemperature protection circuit comprises a temperature comparator. The temperature comparator is configured for receiving a temperature signal referring to a temperature of at least a part of an electronic device. The temperature comparator is further configured for comparing the temperature to a temperature threshold. The overtemperature protection circuit further comprises an evaluation circuit. The evaluation circuit is configured for evaluating a time of temperature exceedance. The evaluation circuit is further configured for declaring an overtemperature condition of the electronic device if the time of temperature exceedance exceeds a time threshold.

In a further aspect, a use of a method for overtemperature protection or of an overtemperature detection circuit is presented for an automotive application.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1a and 1b schematically illustrate examples of an overtemperature detection circuit in conjunction with a monitored electronic device;

FIGS. 2a to 2c schematically illustrate examples of an evaluation circuit of an overtemperature detection circuit;

FIG. 3 schematically illustrates a further example of an overtemperature detection circuit; and

FIG. 4 illustrates a flow chart of an example of a method for overtemperature protection.

### DETAILED DESCRIPTION

The examples described herein provide considerable advantages. Specifically, the presented methods and devices may make use of a device ruggedness against high operation temperatures over limited time periods. More specifically, the presented methods and devices may implement a time-dependent overtemperature protection. Thus, a time period of an overtemperature operation may be monitored and only if the overtemperature operation is too long in time, protective measures may be taken. In other words, a temperature threshold may be connected with a time-dependency. Additionally, a further temperature threshold with no time-dependency may be used for specifying a temperature which should not be exceeded even for a short period of time. Thus, said two temperature thresholds may define a temperature range which may be tolerable for operation for a short period of time, specifically without further damage or at least without further significant damage to a device or without failure or malfunctioning of the device. As a result, an operation range of the device may be extended. Specifically, a short operation at high temperatures may be enabled.

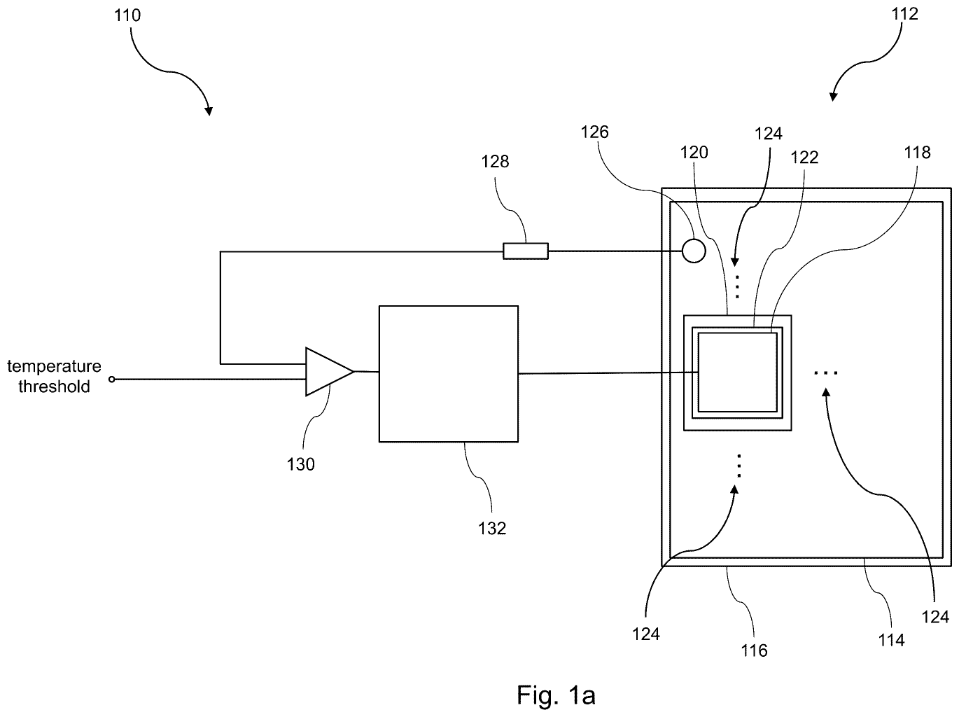

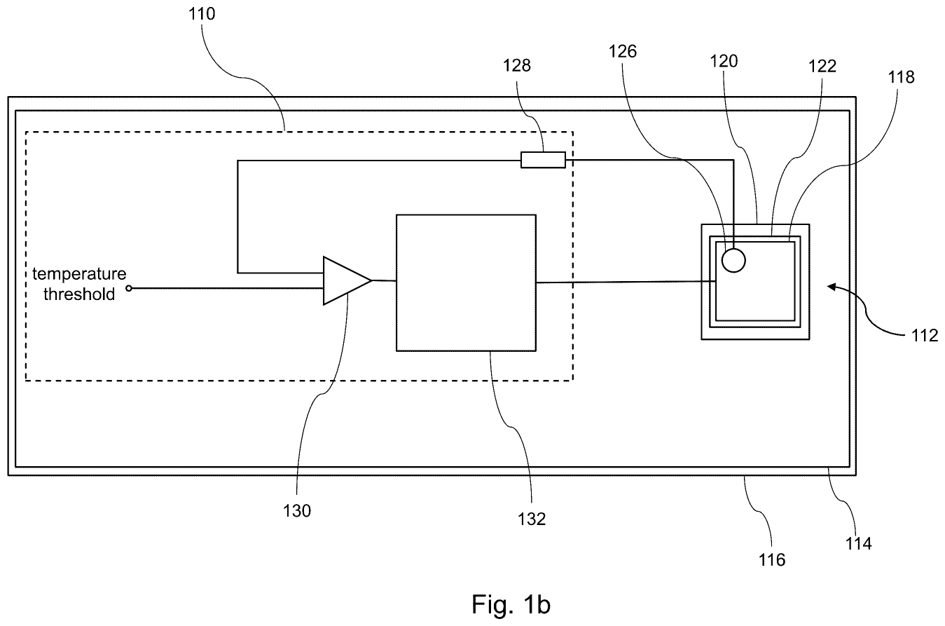

FIG. 1a schematically illustrates an example of an overtemperature detection circuit 110 in conjunction with a monitored electronic device 112. Thus, the overtemperature detection circuit 110 may be configured for detecting an overtemperature condition at the electronic device 112, specifically a damaging overtemperature condition or at least a significantly damaging overtemperature condition. The overtemperature condition may refer to a state in which the electronic device 112 is operated at a temperature causing damage or at least significant damage to the electronic device 112 or a failure or a malfunctioning of the electronic device 112. In principle, the electronic device 112 may be an arbitrary device comprising electronic components. Specifically, the electronic device 112 may be or may comprise a semiconductor device. The electronic device 112 may be or may comprise an integrated circuit. The electronic device 112 may be configured for directly or indirectly controlling an application, specifically an automotive application, e.g. a motor or a light emitting diode. The electronic device 112 may be or may comprise a printed circuit board 114 or at least a part thereof. The printed circuit board 114 may at least partially be surrounded by a housing 116. The printed circuit board 114 may comprise at least one semiconductor die 118. The semiconductor die 118 may be or may comprise an integrated circuit. The semiconductor die 118 may be surrounded by a package 120. The semiconductor die 118 may further be soldered to the printed circuit board 114 by using a solder 122. As an example, depending on the application, the electronic device 112 may comprise the semiconductor die 118 or the even the entire printed circuit board 114. The printed circuit board 114 may comprise a plurality of semiconductor dies 118 or also further components as indicated by dots 124, which may at least partially be interconnected by wires or traces.

The overtemperature detection circuit 110 may comprise a temperature sensor 126. The temperature sensor 126 may be configured for monitoring the temperature of the electronic device 112 or at least of a part thereof. The temperature sensor 126 may for instance be or may comprise a thermistor. The thermistor may be a negative-temperature-coefficient thermistor or a positive-temperature-coefficient thermistor. Other options may also be feasible. As an example, the temperature sensor 126 may be configured for monitoring a temperature of the printed circuit board 114 and/or of the semiconductor die 118. The temperature sensor 126 may be located at the electronic device 112. As shown, the temperature sensor 126 may be located at the printed circuit board 114. However, the temperature sensor 126 may also be located at the semiconductor die 118 or an additional temperature sensor 126 may be located at the semiconductor die 118. The overtemperature detection circuit may also comprise a plurality of temperature sensors 126, specifically at different locations and for monitoring different areas. The temperature sensor 126 may be configured for sending a temperature signal corresponding to the monitored temperature.

The temperature signal may at least initially be an analog temperature signal. However, the analog temperature signal may be converted into a digital temperature signal subsequently. The overtemperature detection circuit 110 may comprise an analog-to-digital converter 128.

The analog-to-digital converter 128 may be configured for converting the analog temperature signal to the digital temperature signal. Thus, the overtemperature detection circuit 110 may at least partially be a digital device. In other words, at least some of the components of the overtemperature detection circuit 110, which will be described below, may be digital components. In principle, the overtemperature detection circuit 110 may however also be an analog device. In other words, the components of the overtemperature detection circuit 110, which will be described below, may also be analog components. Generally, the overtemperature detection circuit 110 may be or may comprise an integrated circuit.

The overtemperature detection circuit 110 comprises a temperature comparator 130. The temperature comparator 130 is a configured for receiving a temperature signal referring to a temperature of at least a part of the electronic device 112. The temperature comparator 130 is further configured for comparing the temperature to a temperature threshold. As indicated, the temperature comparator 130 may be an analog or a digital component. The temperature comparator 130 may be or may comprise an electronic circuit configured for comparing two voltages. A first voltage may refer to the temperature at the electronic device 112. A second voltage may refer to the temperature threshold. An output of the temperature comparator 130 may indicate which voltage is higher and thus if the temperature at the electronic device 112 is higher than the temperature threshold. Thus, the temperature comparator 130 may indicate if a temperature at the electronic device 112 exceeds or goes above the temperature threshold.

The temperature threshold may be predetermined. Thus, the temperature threshold may be a predetermined temperature value or a corresponding voltage value applied to the temperature comparator 130. As an example, the temperature threshold may be in a range from 80° C. to 270° C., specifically from 100° C. to 200° C., more specifically from 130° C. to 175° C. As a specific example, the temperature threshold may be 135° C. The temperature threshold may specifically be tailored to at least one material comprised by the electronic device 112 or more specifically to a temperature resistance of the material. More specifically, the temperature threshold may be tailored to a material with a low temperature resistance or even to a least temperature resistant material of the electronic device 112. As an example, the temperature threshold may be tailored to a component of the electronic device 112 such as the printed circuit board 114, the housing 116, the package 120 or the solder 122. Thus, the temperature threshold may be chosen in order to prevent damage or degradation or failure of such a component. The component may comprise at least one of a synthetic material, a mold resin and a composite material, specifically out of the FR4 class. Thus, the temperature threshold may be a transition temperature of such a material, specifically a glass transition temperature. However, a damage to said component may not necessarily occur instantaneously when exceeding the temperature threshold. A short temperature exceedance may not or at least not significantly damage the electronic device 112. Only a sufficiently long temperature exceedance may do so. Thus, monitoring a time of temperature exceedance may extend an operation range of the electronic device 112.

The overtemperature protection circuit 110 further comprises an evaluation circuit 132. The evaluation circuit 132 is configured for evaluating a time of temperature exceedance. The evaluation circuit 132 is further configured for declaring an overtemperature condition of the electronic device 112 if the time of temperature exceedance exceeds a time threshold. The time threshold may be an individual time threshold. Thus, when a temperature exceedance is detected by the temperature comparator 130, the evaluation circuit 132 may evaluate how long the temperature exceedance lasts, specifically uninterruptedly or continuously. However, the time threshold may also be an accumulated time threshold. The accumulated time threshold may consider a plurality of individual temperature exceedances over time. Thus, the accumulated time threshold may be an overall time threshold for said plurality of individual temperature exceedances over time. As an example, the temperature threshold may be exceeded for a first period of time. After the first period of time, the temperature at the electronic device 112 may again be below the temperature threshold. However, the temperature threshold may then be exceeded for a second period of time. In this example, the sum of the first period of time and the second period of time may be compared to the accumulated time threshold. Each temperature exceedance may damage the electronic device 112 at least a bit and the accumulated time threshold may thus consider an overall damage to the electronic device 112 over time.

The time threshold may be predetermined. Thus, the time threshold may be a fixed time value, e.g. in a range from 1 ms to 100 h, specifically from 10 ms to 1 min, more specifically from 100 ms to 10 s. A time threshold of 100 h may for instance be used for an accumulated time threshold. An individual time threshold, which may for instance be used with respect to a motor start or a charging of a capacitor, may typically be in a range of several milliseconds or seconds. Such operations may occur regularly occur specifically in automotive applications and may heat up control electronics over a temperature threshold of for instance the printed circuit board 114 or at least a part thereof. However, such operations may only be limited in time and the printed circuit board 114 may be capable of withstanding such a short overheating, at least without further significant damage or failure.

However, the time threshold may also be variable. Specifically, the time threshold may also be a function of the temperature, specifically the temperature at the electronic device 112, e.g. at the printed circuit board 114 or at least a part thereof or at the package 120 or at the solder 122. The function may specifically comprise an integral of the temperature over time. Thus, the time threshold may vary depending on the temperature at the electronic device 112. This may specifically take into account further temperature variations, more specifically a further temperature increase, at the electronic device 112. As an example, after exceeding the temperature threshold, the temperature at the electronic device 112 may increase even further, which may put additional stress to the electronic device 112 and may thus further damage the electronic device 112. For considering this additional stress, an integral of the temperature over time may for instance be evaluated. Thus, the time threshold may also be a threshold for the time integral of the temperature or in short a time integral threshold.

As said, the evaluation circuit 132 is configured for declaring an overtemperature condition of the electronic device 112 if the time of temperature exceedance exceeds a time threshold. The evaluation circuit 132 may further be configured for outputting or indicating the overtemperature condition to the electronic device 112, specifically for triggering a remedial reaction. Thus, the evaluation circuit 132 may further be configured for initiating a reaction to the overtemperature condition. The reaction may comprise triggering a safe state of the electronic device 112. The safe state may specifically be an off state of the electronic device 112. In other words, in case of an overtemperature condition, the electronic device may be switched off. Other safe states may however also be feasible. The safe state may in principle also be an on state, e.g. an on state with reduced power consumption. Additionally or alternatively, the reaction may comprise activating a cooling of the electronic device 112. Thus, a cooling element, e.g. a fan or a thermoelectric cooler such as a Peltier cooler, may for instance be switched on and actively cool the electronic device 112.

FIG. 1b schematically illustrates a further example of the overtemperature detection circuit 110. To a large extent, the overtemperature detection circuit 110 shown in FIG. 1b corresponds to the overtemperature detection circuit 110 shown in FIG. 1a. Thus, for the description of FIG. 1b, reference may be made to a large extend to the description of FIG. 1a. As shown in FIG. 1b and as also already indicated, the electronic device 112 may only be a part of the printed circuit board 114 and not necessarily comprise the entire printed circuit board 114. Thus, the electronic device 112 may for instance be or may comprise the semiconductor die 118 on the printed circuit board 114. The temperature sensor 126 may be located at the semiconductor die 114 and may thus measure a temperature at the semiconductor die 118. A temperature at the semiconductor die 118 may however at least be similar to a temperature at the package 120, at the solder 122 or at a part of the printed circuit board 114 surrounding the semiconductor die 118. As said, the temperature threshold may for instance be tailored to these components which may be less temperature resistant compared to the semiconductor die 118, but which may withstand higher temperatures at least for a short period of time. As FIG. 1b further shows, the overtemperature detection circuit 110 may also be located on a printed circuit board 114 and specifically on the same printed circuit board 114 as the electronic device 112.

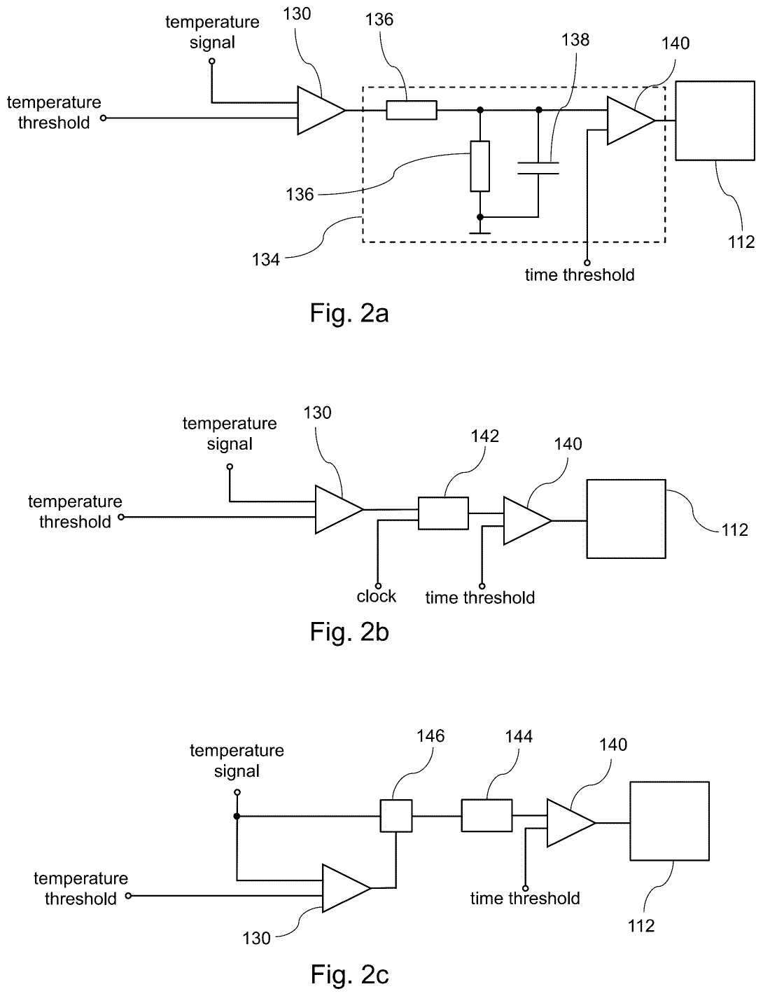

FIGS. 2a to 2c schematically illustrate examples of the evaluation circuit 132 of the overtemperature detection circuit 110. As said, the evaluation circuit 132 is configured for evaluating a time of temperature exceedance and for declaring an overtemperature condition of the electronic device 112 if the time of temperature exceedance exceeds a time threshold. Thus, the evaluation circuit 132 may receive an input signal from the temperature comparator 130 and send an output signal to the electronic device 112. Additionally or alternatively, the evaluation circuit 132 may send an output signal to a further component, e.g. to a cooling element separate from the electronic device 112. As also already indicated, the evaluation circuit 132 may be an analog or a digital circuit. Thus, the evaluation circuit 132 may comprise analog or digital components, which will be described in the following. Generally, a variety of different options for realizing the evaluation circuit 132 may be conceivable.

As FIG. 2a shows, the evaluation circuit 132 may for instance be or may comprise a time filter 134. The time filter 134 may be configured for filtering out a time of temperature exceedance below the time threshold. Again, the time filter 134 may be realized in different ways. Thus, the time filter 134 may be a digital or an analog component. As shown in FIG. 2a, the time filter 134 may comprise resistors 136 and capacitor 138 forming a resistor-capacitor circuit. A time constant of the resistor-capacitor circuit may refer to a charging time of the capacitor 138 and may be determined by a product of the resistance and the capacitance. The evaluation circuit 132, in FIG. 2a specifically the time filter 134, may further comprise a time comparator 140. The time comparator 140 may be configured for comparing the time of temperature exceedance with the time threshold. The time comparator 140 may be or may comprise an electronic circuit configured for comparing two voltages. A first voltage may refer to the time threshold. A second voltage may refer to the time of temperature exceedance indicated by the temperature comparator 130. An output of the time comparator 140 may indicate which voltage is higher and thus if the time of the temperature exceedance is higher than the time threshold. Thus, the time comparator 130 may indicate if the time of temperature exceedance is larger than the time threshold, which may than be indicated to the electronic device 112.

However, as said, other options for implementing the evaluation circuit 132 may also be possible. As FIG. 2b shows, the evaluation circuit 132 may also comprise a timer 142. Thus, when the temperature comparator 130 indicates a temperature exceedance, the timer 142 may be started. The timer 142 may for instance be or may comprise a counter, specifically an up-counter. The timer 142 may have a clock input. Thus, the timer 142 may be configured for monitoring the time of temperature exceedance which may be transmitted to the time comparator 140. Once the amount of time exceeds the time threshold, the time comparator 140 may indicate the overtemperature condition to the electronic device 112.

Further, as already outlined, a time integral over the temperature may also be observed. Thus, as shown in FIG. 2c, the evaluation circuit 132 may also comprise an integrator 144. The integrator 144 may be configured for integrating the temperature over time, such as by integrating an incoming temperature signal over time as long as the temperature comparator 130 indicates a temperature exceedance. Thus, the temperature comparator 130 may for instance trigger a switching element 146 for letting the temperature signal pass to the integrator 140. As an example, the switching element 146 may be a transistor such as a metal-oxide-semiconductor field-effect transistor and the temperature comparator 130 may be connected to a gate of the metal-oxide-semiconductor field-effect transistor for switching the metal-oxide-semiconductor field-effect transistor on and off. The integrator 144 may then transmit the integrated temperature signal to the time comparator 140 for comparing it with the time threshold. As said, the time threshold may also be a function of the temperature and specifically a time integral of the temperature. Thus, the time threshold may also be a time integral threshold. Once the time comparator 140 indicates that the time integral threshold is exceeded this may again be indicated to the electronic device 112.

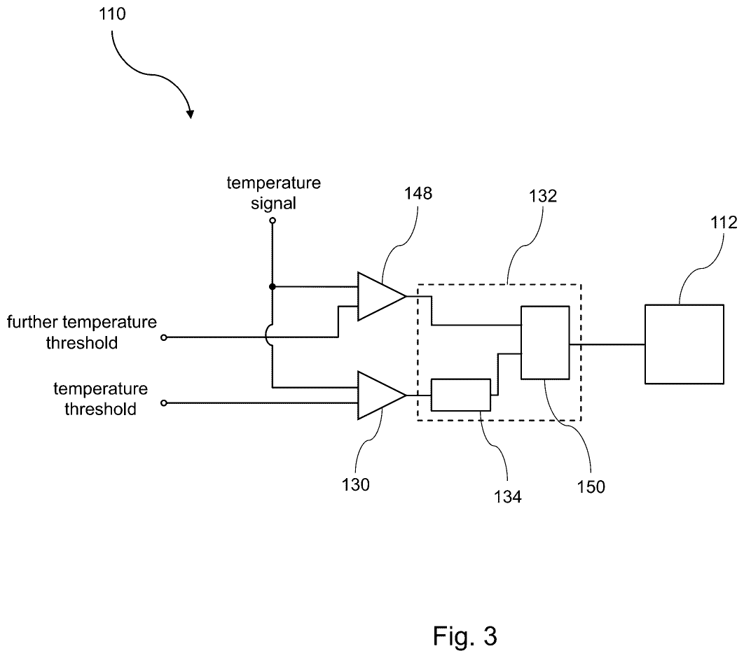

FIG. 3 schematically illustrates a further example of the overtemperature detection circuit 110. To a large extent, the overtemperature detection circuit 110 shown in FIG. 3 corresponds to the overtemperature detection circuit 110 shown in FIG. 1a. Thus, for the description of FIG. 3, reference may be made to a large extend to the description of FIG. 1a. As shown in FIG. 3, the overtemperature detection circuit 110 may specifically comprise a further temperature comparator 148. The further temperature comparator 148 may be configured for comparing the temperature to a further temperature threshold. The further temperature comparator 148 may for instance be of the same type as the temperature comparator 130, but with a further temperature threshold as input which may be different to the temperature threshold of the temperature comparator 130. Specifically, the further temperature threshold of the further temperature comparator 148 may be higher than the temperature threshold of the temperature comparator 130.

The further temperature threshold may also be tailored to at least one material comprised by the electronic device 112 or more specifically to a temperature resistance of the material. Specifically, the further temperature threshold may be tailored to a material with a high temperature resistance or even to a most temperature resistant material of the electronic device 112. As an example, the further temperature threshold may be tailored to the semiconductor die 118 or more specifically to a temperature resistance of the semiconductor die 118. Other options may however also be feasible. The electronic device 112 may for instance further comprise a wire, a trace, a lead frame, a copper tab or a clip and the further temperature threshold may be tailored to such a component. Thus, the further temperature threshold may specifically be tailored to a material selected from the group consisting of a semiconductor, a metal and a ceramic. The semiconductor may specifically be silicon, silicon carbide or gallium nitride. Other options may of course also be conceivable.

The further temperature threshold may be predetermined. Thus, the further temperature threshold may be a predetermined temperature value or a corresponding voltage value applied to the further temperature comparator 148. As an example, the further temperature threshold may be in a range from 100° C. to 400° C., specifically from 150° C. to 300° C., more specifically from 170° C. to 200° C. As a specific example, the further temperature threshold may be 175° C. Such temperatures may damage the above-mentioned materials, specifically even if only applied for a short period of time. Different to the temperature threshold applied to the temperature comparator 130, the further temperature threshold applied to the further threshold comparator 148 may time-independently or instantaneously trigger declaring the overtemperature condition and initiating a corresponding reaction, such as switching off the electronic device 112. Thus, the further temperature threshold may be a maximum temperature value, which a temperature at the electronic device 112 should not exceed, specifically not even for a short period of time.

The evaluation circuit 132 may be configured for time-independently or instantaneously declaring the overtemperature condition of the electronic device 112 if the further temperature threshold is exceeded. As FIG. 3 shows, the evaluation circuit 132 may for instance comprise a time filter 134 and a logic gate 150. The time filter 134 may be connected to the temperature comparator 130 for filtering out times of temperature exceedance below the set time threshold as described before. However, the evaluation circuit 132 may also be implemented differently in principle such as be using the timer 142 instead of the time filter 134 as also described before. The further temperature comparator 148 may however specifically not be connected to such an element. Instead, the further temperature comparator 148 may directly be connected to the logic gate 150. The logic gate 150 may specifically be an OR gate or an XOR gate. Thus, if the further temperature comparator 148 indicates that a temperature at the electronic device 112 exceeds the further temperature threshold, a remedial reaction may directly be initiated, such as switching off the electronic device 112. However, if the temperature comparator 130 indicates that a temperature at the electronic device 112 only exceeds the temperature threshold, which may specifically be lower compared to the further temperature threshold, such a reaction may not directly be initiated. In this case, said reaction may only be initiated if the electronic device 112 stays at such a temperature for a longer period of time compared to the given time threshold.

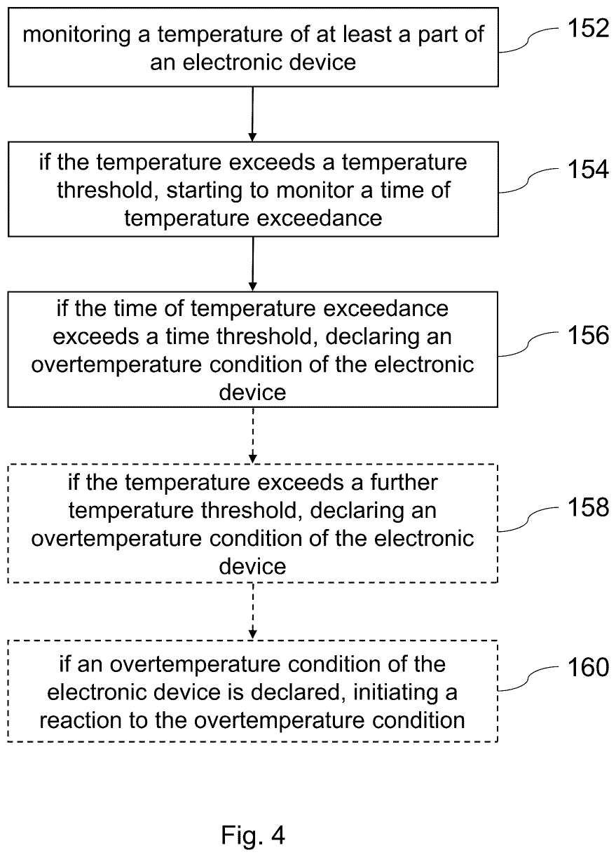

FIG. 4 illustrates a flow chart of an example of a method for overtemperature protection. The method comprises the following steps. The presented method steps may be performed in the indicated order. It shall be noted, however, that a different order may also be possible. The method may comprise further method steps which are not listed. Further, one or more of the method steps may be performed once or repeatedly. Further, two or more of the method steps may be performed simultaneously or in a timely overlapping fashion. The method may at least partially be computer-implemented. Thus, one or more of the following method steps may be computer-implemented.
a) (denoted by reference numeral 152) monitoring a temperature of at least a part of the electronic device 112;
b) (denoted by reference numeral 154) if the temperature exceeds a temperature threshold, starting to monitor a time of temperature exceedance; and
c) (denoted by reference numeral 156) if the time of temperature exceedance exceeds a time threshold, declaring an overtemperature condition of the electronic device 112.

The method may further comprise the following steps:
d) (denoted by reference numeral 158) if the temperature exceeds a further temperature threshold, declaring an overtemperature condition of the electronic device 112; and
e) (denoted by reference numeral 160) if an overtemperature condition of the electronic device 112 is declared, initiating a reaction to the overtemperature condition.

As already outlined above in further detail, the time threshold may be a function of the temperature. The function may be or may comprise an integral of the temperature over time. Further, the time threshold may be an individual time threshold or an accumulated threshold. As an example, the time threshold may be in a range from 1 ms to 100 h, specifically from 10 ms to 1 min, more specifically from 100 ms to 10 s. The temperature threshold may be tailored to at least one material comprised by the electronic device 112 or more specifically to a temperature resistance of the material. Specifically, the temperature threshold may be tailored to a material with a low temperature resistance or even to a least temperature resistant material of the electronic device 112. As an example, the electronic device 112 may comprise a component selected from the group consisting of: a printed circuit board or at least a part thereof; a housing; a package; a solder. The temperature threshold may be tailored to said component. The component may comprise at least one of a synthetic material, a mold resin and a composite material, specifically out of the FR4 class. As an example, the temperature threshold may be in a range from 80° C. to 270° C., specifically from 100° C. to 200° C., more specifically from 130° C. to 175° C. As a specific example, the temperature threshold may 135° C.

The further temperature threshold referred to in step d) may specifically be higher than the temperature threshold referred to in step b). Step d) may comprise declaring the overtemperature condition of the electronic device time-independently or instantaneously. The further temperature threshold may also be tailored to at least one material comprised by the electronic device 112 or more specifically to a temperature resistance of the material. Specifically, the further temperature threshold may be tailored to a material with a high temperature resistance or to a most temperature resistant material of the electronic device 112. As an example, the electronic device 112 may comprise at least one further component selected from the group consisting of: a semiconductor die; a wire; a trace; a lead frame; a copper tab; a clip. The further temperature threshold may be tailored to said further component. The further component may comprise at least one of a semiconductor, specifically silicon, silicon carbide, gallium nitride; a metal; a ceramic. As an example, the further temperature threshold may be in a range from 100° C. to 400° C., specifically from 150° C. to 300° C., more specifically from 170° C. to 200° C. As a specific example, the further temperature threshold may be 175° C. The reaction in step e) may comprise triggering a safe state of the electronic device 112. The safe state may be an off state of the electronic device 112. Additionally or alternatively, the reaction may comprise activating a cooling of the electronic device 112.

For further details, reference may also be made to the descriptions of FIG. 1a to FIG. 3 above.

The described method or the overtemperature detection circuit 110 may specifically be used for an automotive application. As said, the electronic device 112 may specifically be configured for controlling an automotive application, e.g. a motor. Thus, the method or the overtemperature detection circuit 110 may specifically be used for overtemperature detection or overtemperature protection of an automotive application or within an automotive application. Generally, other applications may of course also be feasible.

In addition to the above described examples, the following examples are disclosed herein:

Example 1: A method for overtemperature protection of an electronic device, the method comprising:
a) monitoring a temperature of at least a part of the electronic device;
b) if the temperature exceeds a temperature threshold, starting to monitor a time of temperature exceedance; and
c) if the time of temperature exceedance exceeds a time threshold, declaring an overtemperature condition of the electronic device.

Example 2: The method according to the preceding Example, wherein the time threshold is a function of the temperature.

Example 3: The method according to the preceding Example, wherein the function comprises an integral of the temperature over time.

Example 4: The method according to any one of the preceding Examples, wherein the time threshold is an individual time threshold.

Example 5: The method according to any one of the preceding Examples, wherein the time threshold is an accumulated time threshold.

Example 6: The method according to any one of the preceding Examples, wherein the time threshold is in a range from 1 ms to 100 h, specifically from 10 ms to 1 min, more specifically from 100 ms to 10 s.

Example 7: The method according to any one of the preceding Examples, wherein the temperature threshold is tailored to at least one material comprised by the electronic device.

Example 8: The method according to any one of the preceding Examples, wherein the temperature threshold is tailored to a least temperature resistant material of the electronic device.

Example 9: The method according to any one of the preceding Examples, wherein the electronic device comprises a component selected from the group consisting of: a printed circuit board or at least a part thereof; a housing; a package; a solder.

Example 10: The method according to the preceding Example, wherein the temperature threshold is tailored to the component.

Example 11: The method according to any one of the two preceding Examples, wherein the component comprises at least one of a synthetic material; a mold resin; a composite material, specifically out of the FR4 class.

Example 12: The method according to any one of the preceding Examples, wherein the temperature threshold is in a range from 80° C. to 270° C., specifically from 100° C. to 200° C., more specifically from 130° C. to 175° C.

Example 13: The method according to any one of the preceding Examples, wherein the temperature threshold is 135° C.

Example 14: The method according to any one of the preceding Examples, further comprising:
d) if the temperature exceeds a further temperature threshold, declaring an overtemperature condition of the electronic device.

Example 15: The method according to the preceding Example, wherein the further temperature threshold referred to in step d) is higher than the temperature threshold referred to in step b).

Example 16: The method according to any one of the two preceding Examples, wherein step d) comprises declaring the overtemperature condition of the electronic device time-independently.

Example 17: The method according to any one of the three preceding Examples, wherein the further temperature threshold is tailored to at least one material comprised by the electronic device.

Example 18: The method according to any one of the four preceding Examples, wherein the further temperature threshold is tailored to a most temperature resistant material of the electronic device.

Example 19: The method according to any one of the five preceding Examples, wherein the electronic device comprises at least one further component selected from the group consisting of: a semiconductor die; a wire; a trace; a lead frame; a copper tab; a clip.

Example 20: The method according to the preceding Example, wherein the further temperature threshold is tailored to the further component.

Example 21: The method according to any one of the two preceding Examples, wherein the further component comprises at least one of a semiconductor, specifically silicon, silicon carbide, gallium nitride; a metal; a ceramic.

Example 22: The method according to any one of the eight preceding Examples, wherein the further temperature threshold is in a range from 100° C. to 400° C., specifically from 150° C. to 300° C., more specifically from 170° C. to 200° C.

Example 23: The method according to any one of the nine preceding Examples, wherein the further temperature threshold is 175° C.

Example 24: The method according to any one of the preceding Examples, further comprising:
e) if an overtemperature condition of the electronic device is declared, initiating a reaction to the overtemperature condition.

Example 25: The method according to the preceding Example, wherein the reaction comprises triggering a safe state of the electronic device.

Example 26: The method according to the preceding Example, wherein the safe state is an off state of the electronic device.

Example 27: The method according to any one of the three preceding Examples, wherein the reaction comprises activating a cooling of the electronic device.

Example 28: The method according to any one of the preceding Examples, wherein the electronic device is configured for directly or indirectly controlling an application, specifically an automotive application, more specifically a motor or a light emitting diode.

Example 29: The method according to any one of the preceding Examples, wherein the electronic device is a semiconductor device.

Example 30: The method according to any one of the preceding Examples, wherein the electronic device comprises an integrated circuit.

Example 31: The method according to any one of the preceding Examples, wherein the method is at least partially computer implemented.

Example 32: An overtemperature detection circuit comprising:
a temperature comparator configured for receiving a temperature signal referring to a temperature of at least a part of an electronic device and for comparing the temperature to a temperature threshold; and
an evaluation circuit configured for evaluating a time of temperature exceedance and for declaring an overtemperature condition of the electronic device if the time of temperature exceedance exceeds a time threshold.

Example 33: The overtemperature detection circuit according to the preceding Example, wherein the overtemperature detection circuit is configured for performing a method for overtemperature protection of an electronic device according to any one of the preceding method Examples.

Example 34: The overtemperature detection circuit according to any one of the preceding Examples referring to an overtemperature detection circuit, wherein the evaluation circuit comprises a time filter configured for filtering out a time of temperature exceedance below the time threshold.

Example 35: The overtemperature detection circuit according to any one of the preceding Examples referring to an overtemperature detection circuit, wherein the evaluation circuit comprises a timer configured for monitoring a time of temperature exceedance.

Example 36: The overtemperature detection circuit according to any one of the preceding Examples referring to an overtemperature detection circuit, wherein the evaluation circuit comprises a time comparator configured for comparing the time of temperature exceedance with the time threshold.

Example 37: The overtemperature detection circuit according to any one of the preceding Examples referring to an overtemperature detection circuit, wherein the evaluation circuit comprises an integrator configured for integrating the temperature over time.

Example 38: The overtemperature detection circuit according to any one of the preceding Examples referring to an overtemperature detection circuit, further comprising:
a further temperature comparator configured for comparing the temperature to a further temperature threshold.

Example 39: The overtemperature detection circuit according to the preceding Example, wherein the evaluation circuit is configured for time-independently declaring the overtemperature condition of the electronic device if the further temperature threshold is exceeded.

Example 40: The overtemperature detection circuit according to any one of the preceding Examples referring to an overtemperature detection circuit, further comprising:
at least one temperature sensor configured for monitoring the temperature of the electronic device or at least of a part thereof and for sending a corresponding temperature signal.

Example 41: The overtemperature detection circuit according to the preceding Example, wherein the temperature sensor is located at the electronic device.

Example 42: The overtemperature detection circuit according to any one of the preceding Examples referring to an overtemperature detection circuit, wherein the evaluation circuit is further configured for outputting the overtemperature condition to the electronic device.

Example 43: The overtemperature detection circuit according to the preceding Example, wherein the evaluation circuit is further configured for initiating a reaction to the overtemperature condition.

Example 44: The overtemperature detection circuit according to any one of the preceding Examples referring to an overtemperature detection circuit, wherein the temperature signal is an analog temperature signal, wherein the overtemperature detection circuit further comprises:
an analog-to-digital converter configured for converting the analog temperature signal to a digital temperature signal.

Example 45: The overtemperature detection circuit according to any one of the preceding Examples referring to an overtemperature detection circuit, wherein at least one of the temperature comparator, the evaluation circuit and optionally the further temperature comparator is a digital component.

Example 46: The overtemperature detection circuit according to any one of the preceding Examples referring to an overtemperature detection circuit, wherein the overtemperature detection circuit comprises an integrated circuit.

Example 47: A use for an automotive application of at least one of a method for overtemperature protection according to any one of the preceding method Examples and an overtemperature detection circuit according to any one of the preceding Examples referring to an overtemperature detection circuit.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A method for overtemperature protection of an electronic device, the method comprising:
a) monitoring a temperature of at least a part of the electronic device;
b) if the temperature exceeds a temperature threshold, starting to monitor a time of temperature exceedance; and
c) if the time of temperature exceedance exceeds a time threshold, declaring an overtemperature condition of the electronic device.

2. The method of claim 1, wherein the time threshold is a function of the temperature.

3. The method of claim 2, wherein the function comprises an integral of the temperature over time.

4. The method of claim 1, wherein the time threshold is an accumulated time threshold.

5. The method of claim 1, wherein the temperature threshold is tailored to a least temperature resistant material of the electronic device.

6. The method of claim 1, further comprising:
d) if the temperature exceeds a further temperature threshold, declaring an overtemperature condition of the electronic device.

7. The method of claim 6, wherein step d) comprises declaring the overtemperature condition of the electronic device time-independently.

8. The method according to claim 6, wherein the further temperature threshold is tailored to a most temperature resistant material of the electronic device.

9. The method according to claim 6, further comprising:
e) if an overtemperature condition of the electronic device is declared, initiating a reaction to the overtemperature condition.

10. The method according to claim 9, wherein the reaction comprises triggering a safe state of the electronic device.

11. The method according to claim 9, wherein the reaction comprises activating a cooling of the electronic device.

12. An overtemperature detection circuit comprising:
a temperature comparator configured to receive a temperature signal referring to a temperature of at least a part of an electronic device and to compare the temperature to a temperature threshold; and
an evaluation circuit configured to evaluate a time of temperature exceedance and to declare an overtemperature condition of the electronic device if the time of temperature exceedance exceeds a time threshold.

13. The overtemperature detection circuit according to claim 12, wherein the evaluation circuit comprises a time filter configured for filtering out a time of temperature exceedance below the time threshold.

14. The overtemperature detection circuit according to claim 12, wherein the evaluation circuit comprises a timer configured to monitor a time of temperature exceedance.

15. The overtemperature detection circuit according to claim 12, wherein the evaluation circuit comprises a time comparator configured to compare the time of temperature exceedance with the time threshold.

16. The overtemperature detection circuit according to claim 12, wherein the evaluation circuit comprises an integrator configured to integrate the temperature over time.

17. The overtemperature detection circuit according to claim 12, further comprising:
a further temperature comparator configured to compare the temperature to a further temperature threshold.

18. The overtemperature detection circuit according to claim 12, further comprising:
at least one temperature sensor configured to monitor the temperature of the electronic device or at least of a part thereof and to send a corresponding temperature signal.

19. The overtemperature detection circuit according to claim 12, wherein the temperature signal is an analog temperature signal, wherein the overtemperature detection circuit further comprises:
an analog-to-digital converter configured to convert the analog temperature signal to a digital temperature signal.

20. (canceled)
